(19) United States
(12) Patent Application Publication
(10) Pub. No.: US 2025/0220842 A1
(43) Pub. Date: Jul. 3, 2025

(54) CHASSIS

(71) Applicant: Wiwynn Corporation, New Taipei City (TW)

(72) Inventors: Shih-Hung Chen, New Taipei City (TW); Nicholas Chang, New Taipei City (TW); Bo-Kai Wang, New Taipei City (TW); Ming-Chih Kao, New Taipei City (TW)

(73) Assignee: Wiwynn Corporation, New Taipei City (TW)

(21) Appl. No.: 18/754,192

(22) Filed: Jun. 26, 2024

(30) Foreign Application Priority Data
Dec. 29, 2023 (TW) 112151493

(51) Int. Cl. H05K 7/14

(52) U.S. Cl. CPC H05K 7/1487

(57) ABSTRACT

A chassis includes a fixing base, an operating member, a tray and a cover. The operating member is pivotally connected to the fixing base. The operating member includes a first linkage portion. The tray is disposed on the fixing base. The tray includes a second linkage portion corresponding to the first linkage portion. The cover is disposed on the fixing base and covers the tray. When the operating member is located at a closed position, the operating member and the fixing base are locked, and the first linkage portion blocks the second linkage portion, so as to fix the tray on the fixing base. When the operating member rotates from the closed position to an opened position, the first linkage portion pushes the second linkage portion to drive the tray to move toward outside of the fixing base.

### BACKGROUND OF THE INVENTION

### 1. Field of the Invention

The invention relates to a chassis and, more particularly, to a chassis that is easy to be assembled and low-cost.

### 2. Description of the Prior Art

With the rise of big data, machine learning, the Internet of Things, and various network platforms, the demand for servers in life is getting higher and higher. In general, a tray may be disposed in a server chassis to carry a circuit board and other related electronic components. At present, in the prior art, inner and outer rails are disposed on the chassis and the tray respectively, such that the tray is installed in the chassis by a sliding manner. However, the price of the rails is high, which increases the manufacturing cost of the server. Furthermore, the tray is equipped with a handle, such that the tray can be extracted by the handle. However, the mechanism of the handle is complicated and occupies space, which is not conducive to an automated assembly of tray, circuit board and related electronic components.

### SUMMARY OF THE INVENTION

According to an embodiment of the invention, a chassis comprises a fixing base, an operating member, a tray and a cover. The operating member is pivotally connected to the fixing base. The operating member comprises a first linkage portion. The tray is disposed on the fixing base. The tray comprises a second linkage portion corresponding to the first linkage portion. The cover is disposed on the fixing base and covers the tray. When the operating member is located at a closed position, the operating member and the fixing base are locked, and the first linkage portion blocks the second linkage portion, so as to fix the tray on the fixing base. When the operating member rotates from the closed position to an opened position, the first linkage portion pushes the second linkage portion to drive the tray to move toward outside of the fixing base.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a chassis according to an embodiment of the invention.

FIG. 2 is an exploded view illustrating the chassis.

FIG. 3 is a perspective view illustrating an operating member located at an opened position.

FIG. 4 is a perspective view illustrating the operating member located at a closed position.

FIG. 5 is a partial perspective view illustrating a fixing base.

FIG. 6 is a partial perspective view illustrating the fixing base from another viewing angle.

FIG. 7 is a perspective view illustrating the operating member and a pivot.

FIG. 8 is a perspective view illustrating a tray.

FIG. 9 is a perspective view illustrating the tray from another viewing angle.

FIG. 10 is a top view illustrating the operating member located at the opened position.

FIG. 11 is a top view illustrating the operating member located at the closed position.

### DETAILED DESCRIPTION

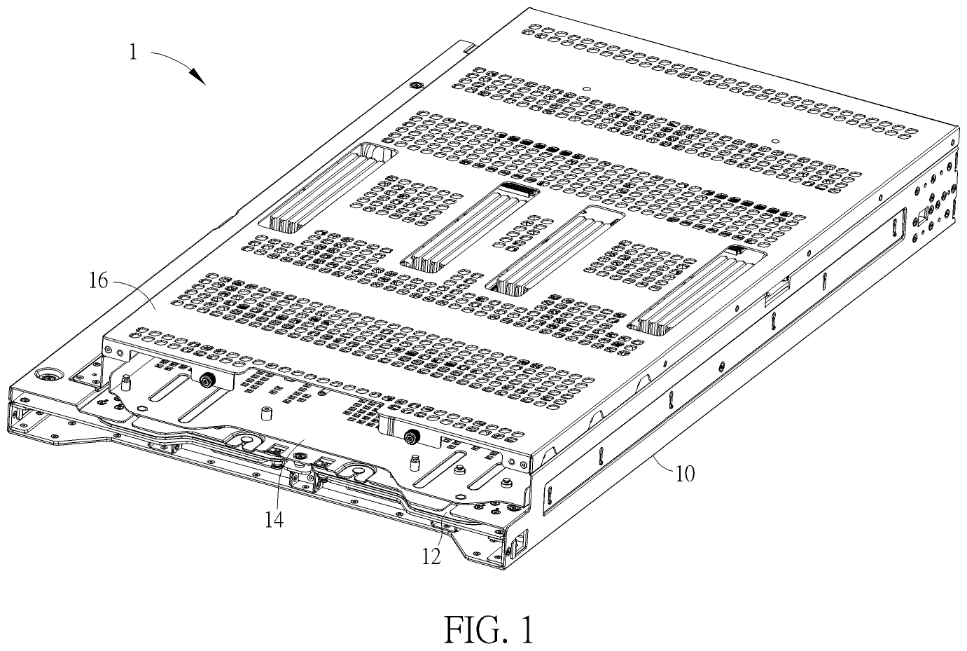

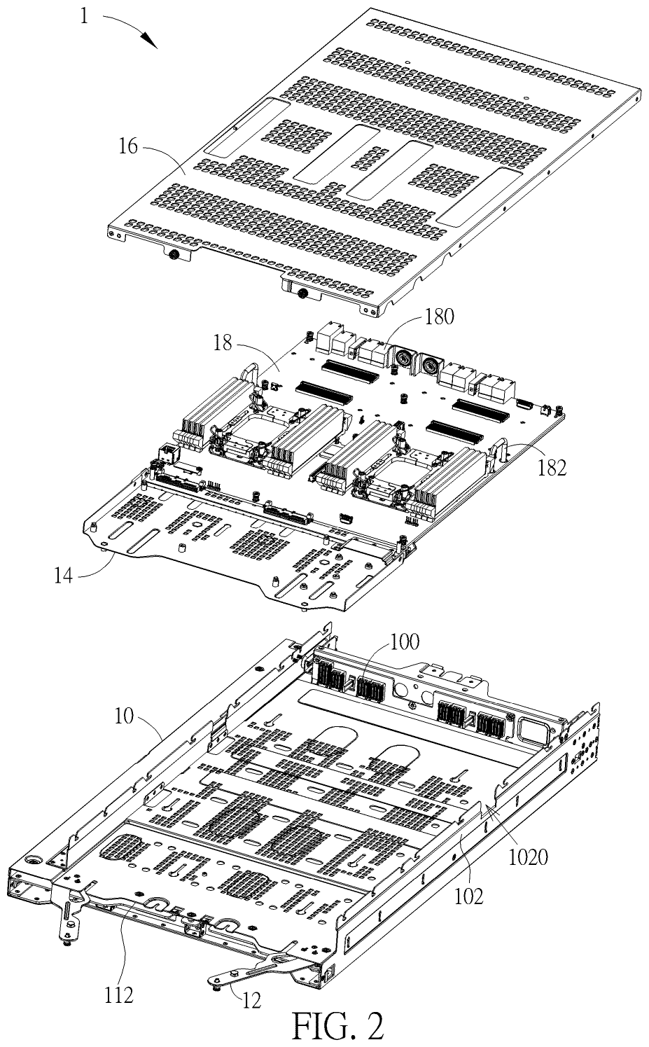

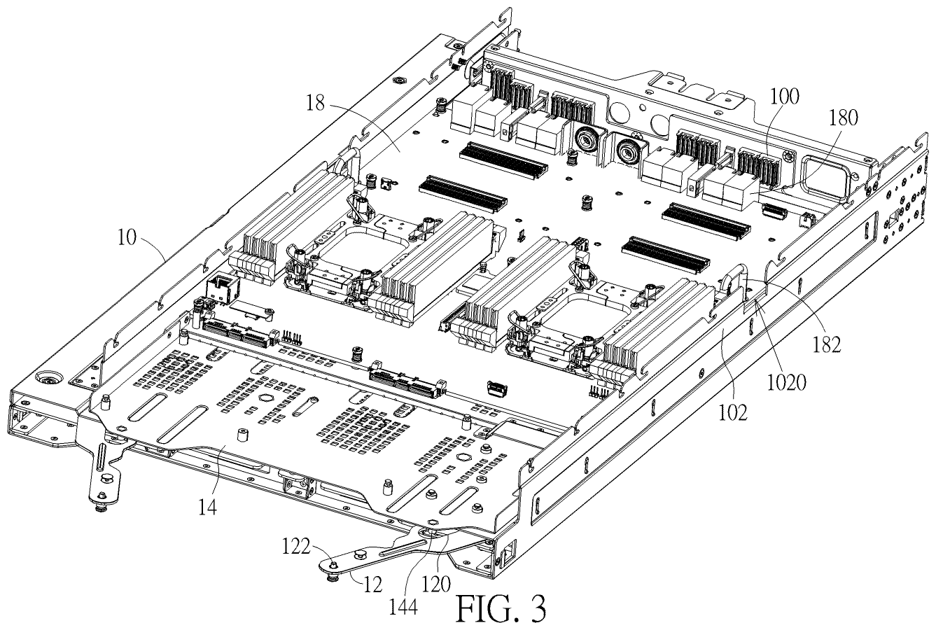

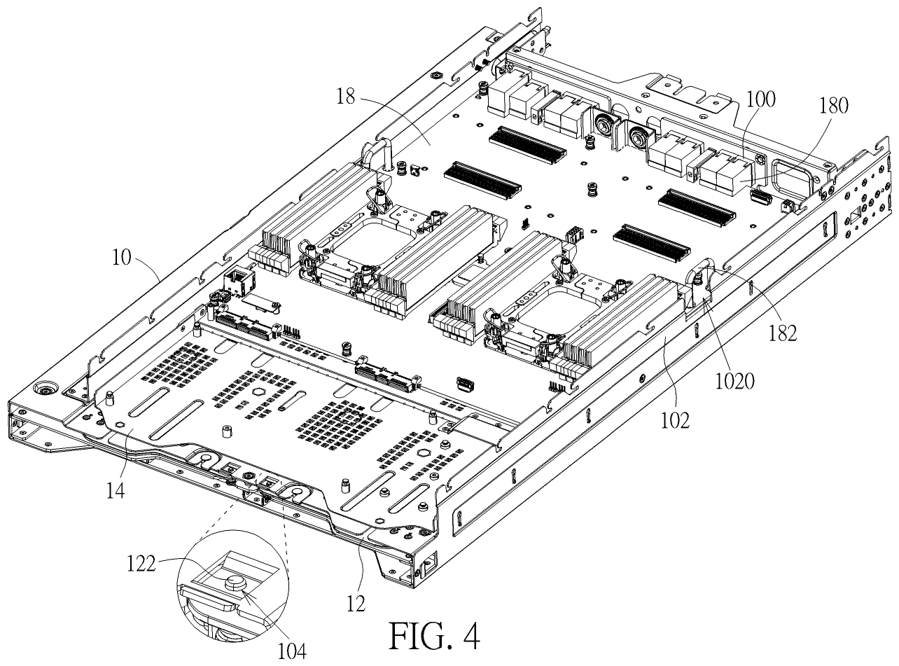

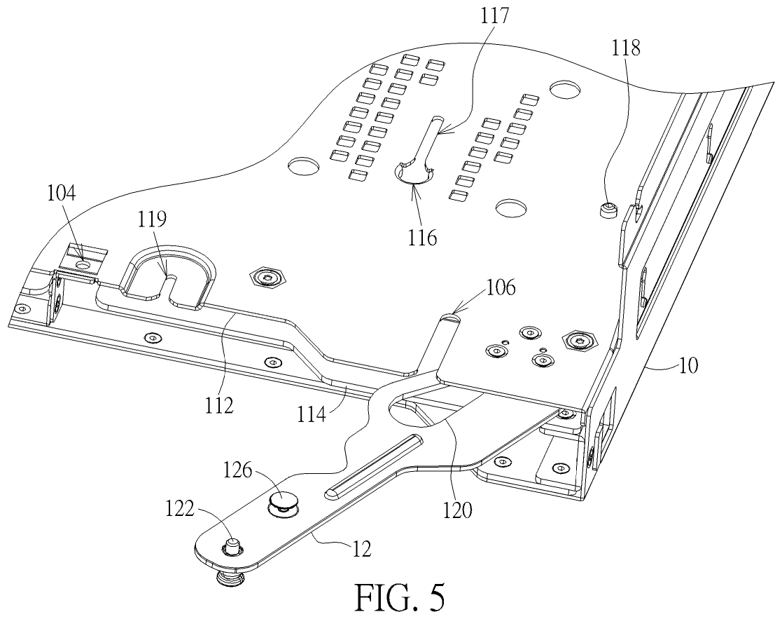

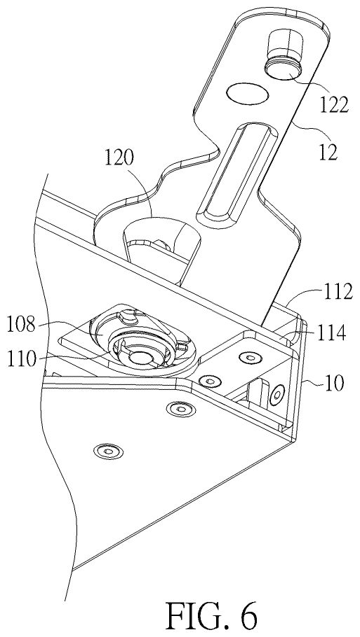

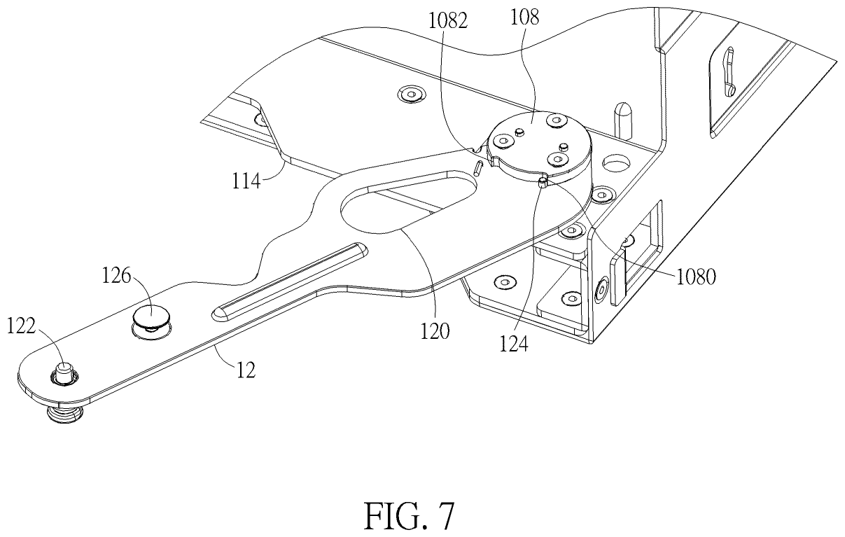

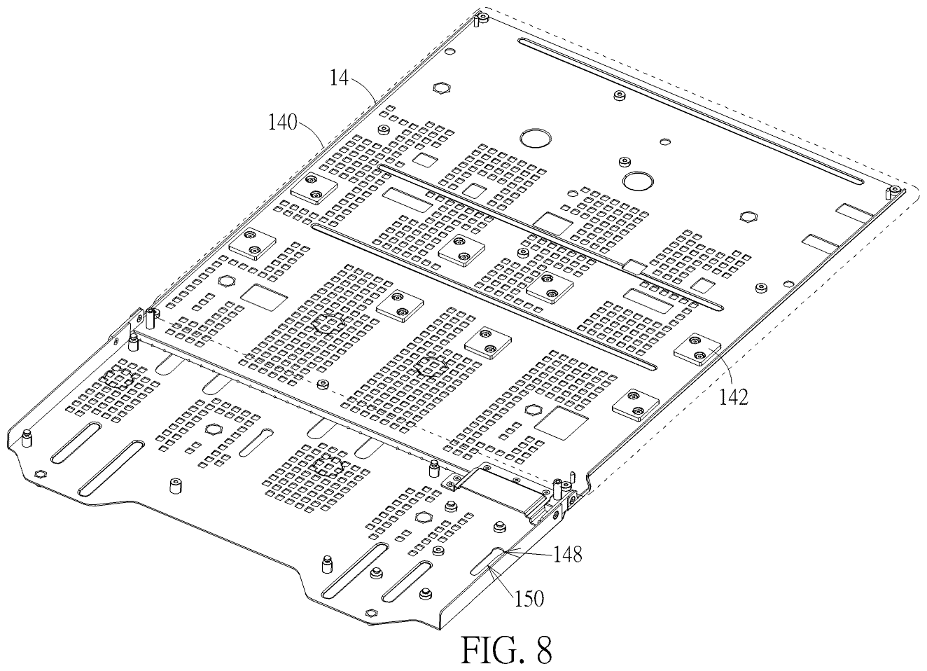

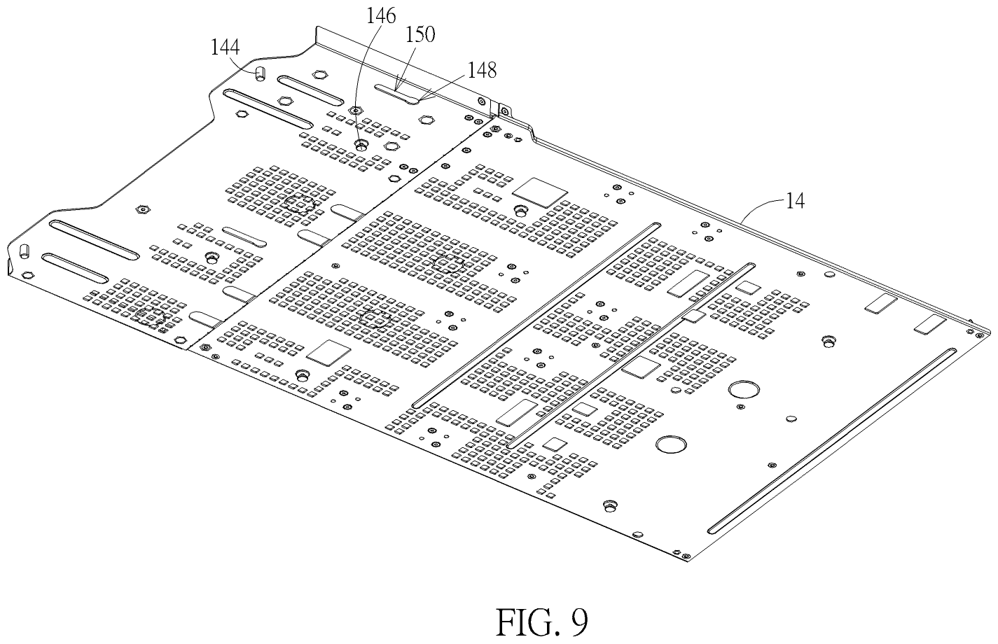

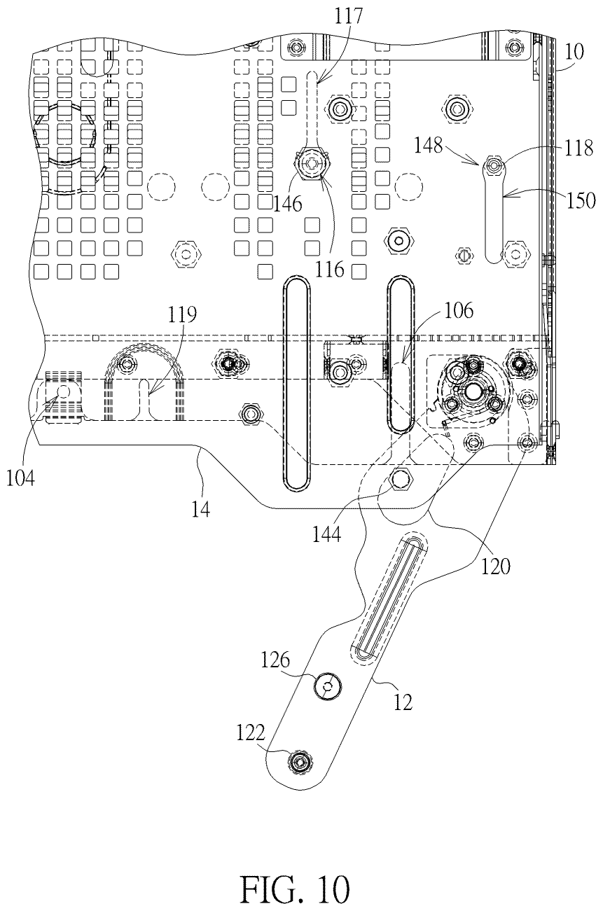

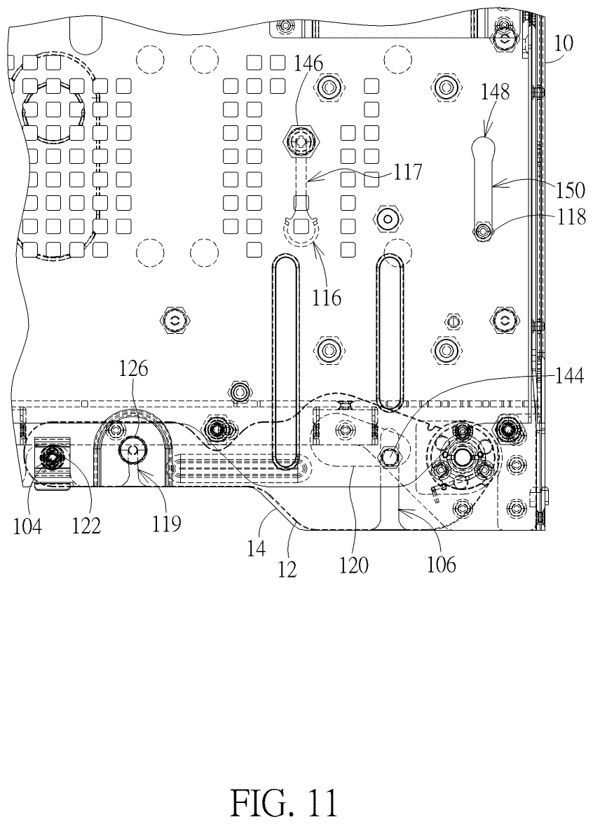

Referring to FIGS. 1 to 11, FIG. 1 is a perspective view illustrating a chassis 1 according to an embodiment of the invention, FIG. 2 is an exploded view illustrating the chassis 1, FIG. 3 is a perspective view illustrating an operating member 12 located at an opened position, FIG. 4 is a perspective view illustrating the operating member 12 located at a closed position, FIG. 5 is a partial perspective view illustrating a fixing base 10, FIG. 6 is a partial perspective view illustrating the fixing base 10 from another viewing angle, FIG. 7 is a perspective view illustrating the operating member 12 and a pivot 108, FIG. 8 is a perspective view illustrating a tray 14, FIG. 9 is a perspective view illustrating the tray 14 from another viewing angle, FIG. 10 is a top view illustrating the operating member 12 located at the opened position, and FIG. 11 is a top view illustrating the operating member 12 located at the closed position.

As shown in FIGS. 1 to 4, the chassis 1 comprises a fixing base 10, an operating member 12, a tray 14 and a cover 16. The operating member 12 is pivotally connected to the fixing base 10, such that the operating member 12 can rotate between an opened position shown in FIG. 3 and a closed position shown in FIG. 4. The tray 14 is disposed on the fixing base 10. The cover 16 is disposed on the fixing base 10 and covers the tray 14. In practical applications, the chassis 1 may comprise two operating members 12 pivotally connected to opposite sides of the fixing base 10, but the invention is not so limited.

In an embodiment, the chassis 1 may be a server chassis. At this time, the chassis 1 may further comprise a circuit board 18 disposed on the tray 14. Furthermore, the circuit board 18 may comprise a first electrical connector 180 and the fixing base 10 may comprise a second electrical connector 100. As shown in FIGS. 2 and 3, when the operating member 12 is located at the opened position, a user may put the tray 14 downward on the fixing base 10. Then, the user may rotate the operating member 12 from the opened position to the closed position shown in FIG. 4. When the operating member 12 rotates from the opened position to the closed position, the operating member 12 drives the tray 14 to move toward inside of the fixing base 10, such that the first electrical connector 180 is connected to the second electrical connector 100. Then, the user may install the cover 16 to the fixing base 10. Accordingly, the assembly of the chassis 1 can be easily completed. When the user wants to take out the tray 14 from the chassis 1, the user needs to detach the cover 16 first. Then, the user may rotate the operating member 12 from the closed position to the opened position. When the operating member 12 rotates from the closed position to the opened position, the operating member 12 drives the tray 14 to move toward outside of the fixing base 10, such that the first electrical connector 180 is separated from the second electrical connector 100. Then, the user may take out the tray upward from the fixing base 10.

In this embodiment, the circuit board 18 may be disposed on an installation region 140 (as shown in FIG. 8) of the tray 14, wherein there is no side wall around the installation region 140. Thus, after the circuit board 18 is put on the installation region 140 of the tray 14, an automated machine may be used to fasten screws and insert electronic components (e.g. memory modules) on the circuit board 18. Since there is no side wall around the installation region 140, a robot arm or the like of the automated machine will not interfere with the tray 14. Thus, the tray 14 is conducive to an automated assembly with the circuit board 18.

In this embodiment, the tray 14 may further comprise a support member 142 disposed on the installation region 140. The support member 142 is configured to support the circuit board 18, so as to prevent the circuit board 18 from being damaged by pressure during the automated assembly process. It should be noted that the number and position of the support members may be determined according to practical applications, so the invention is not limited to the embodiment shown in the figure.

In this embodiment, the circuit board 18 may comprise a handle 182 and the fixing base 10 may comprise a side wall 102, wherein the side wall 102 comprises an indentation 1020 and a position of the indentation 1020 corresponds to a position of the handle 182. The handle 182 may also be assembled to the circuit board 18 by the automated machine. In practical applications, two handles 182 may be disposed on opposite sides of the circuit board 18. The user may hold the handle 182 to put the tray 14 on the fixing base 10 or take out the tray 14 from the fixing base 10. The indentation 1020 can prevent the finger of the user from interfering with the side wall 102 of the fixing base 10.

As shown in FIG. 5, the operating member 12 comprises a first linkage portion 120. As shown in FIG. 9, the tray 14 comprises a second linkage portion 144 corresponding to the first linkage portion 120. In this embodiment, the first linkage portion 120 may be a hole and the second linkage portion 144 may be a protruding pillar, but the invention is not so limited. When the tray 14 is disposed on the fixing base 10, the second linkage portion 144 is located in the first linkage portion 120, as shown in FIG. 3. Furthermore, as shown in FIG. 5, the fixing base 10 comprises a first engaging portion 104 and the operating member 12 comprises a second engaging portion 122. In this embodiment, the first engaging portion 104 may be a hole and the second engaging portion 122 may be a plunger, but the invention is not so limited.

As shown in FIGS. 4 and 11, when the operating member 12 is located at the closed position, the second engaging portion 122 engages with the first engaging portion 104, such that the operating member 12 and the fixing base 10 are locked. At the same time, the first linkage portion 120 blocks the second linkage portion 144, so as to fix the tray 14 on the fixing base 10. At this time, the first electrical connector 180 is connected to the second electrical connector 100. The user may pull the second engaging portion 122 downward to disengage the second engaging portion 122 from the first engaging portion 104, and then rotate the operating member 12 from the closed position to the opened position. When the operating member 12 rotates from the closed position to the opened position, the first linkage portion 120 pushes the second linkage portion 144 to drive the tray 14 to move toward the outside of the fixing base 10, as shown in FIGS. 3 and 10. At this time, the tray 14 drives the circuit board 18 to move toward the outside of the fixing base 10, such that the first electrical connector 180 is separated from the second electrical connector 100. On the other hand, when the operating member 12 rotates from the opened position to the closed position, the first linkage portion 120 pushes the second linkage portion 144 to drive the tray 14 to move toward the inside of the fixing base 10. At this time, the tray 14 drives the circuit board 18 to move toward the inside of the fixing base 10, such that the first electrical connector 180 is connected to the second electrical connector 100. At the same time, the second engaging portion 122 engages with the first engaging portion 104, such that the operating member 12 and the fixing base 10 are locked.

In this embodiment, the fixing base 10 may comprise an avoidance groove 106. As shown in FIGS. 10 and 11, when the operating member 12 rotates between the opened position and the closed position, the second linkage portion 144 may move in the avoidance groove 106, so as to prevent the second linkage portion 144 from interfering with the fixing base 10.

In this embodiment, the fixing base 10 may comprise a pivot 108 and a torsion spring 110, as shown in FIGS. 6 and 7. The operating member 12 is pivotally connected to the pivot 108. The torsion spring 110 is disposed on the pivot 108 and abuts against the operating member 12. As shown in FIGS. 3 and 10, when the second engaging portion 122 disengages from the first engaging portion 104, the torsion spring 110 drives the operating member 12 to rotate toward the opened position. In this embodiment, the fixing base 10 may comprise an upper plate 112. The tray 14 and the operating member 12 are located at opposite sides of the upper plate 112. Accordingly, when the operating member 12 rotates between the opened position and the closed position, the operating member 12 will not interfere with the tray 14. In this embodiment, the fixing base 10 may further comprise a front bezel 114, wherein the operating member 12 is located between the upper plate 112 and the front bezel 114. When the operating member 12 is located at the closed position, the operating member 12 may be wholly accommodated in a space between the upper plate 112 and the front bezel 114.

As shown in FIG. 7, the pivot 108 may comprise two stop portions 1080, 1082, and the operating member 12 may comprise a protruding portion 124, wherein the protruding portion 124 is located between the two stop portions 1080, 1082. The two stop portions 1080, 1082 are configured to stop the protruding portion 124, so as to restrain a rotating range of the operating member 12.

As shown in FIG. 5, the fixing base 10 may comprise a through hole 116, a first restraining groove 117 and a positioning portion 118, wherein the through hole 116 communicates with the first restraining groove 117. In this embodiment, the through hole 116, the first restraining groove 117 and the positioning portion 118 are located on the upper plate 112 of the fixing base 10. Furthermore, as shown in FIGS. 8 and 9, the tray 14 may comprise a first restraining portion 146, a positioning hole 148 and a longitudinal groove 150, wherein the positioning hole 148 communicates with the longitudinal groove 150. In this embodiment, the first restraining portion 146, the positioning hole 148 and the longitudinal groove 150 are located beyond a range of the installation region 140. Thus, after the circuit board 18 is disposed on the installation region 140 of the tray 14, the circuit board 18 will not interfere with the first restraining portion 146, the positioning hole 148 and/or the longitudinal groove 150.

In this embodiment, since the first restraining portion 146 is located on a bottom surface of the tray 14, the user cannot align and insert the first restraining portion 146 with the through hole 116. Thus, as shown in FIG. 10, the user may align the positioning hole 148 of the tray 14 with the positioning portion 118 of the fixing base 10 to put the tray 14 on the fixing base 10. When the positioning portion 118 is inserted into the positioning hole 148, the first restraining portion 146 is inserted into the through hole 116. Then, when the user rotates the operating member 12 from the opened position to the closed position shown in FIG. 11, the first restraining portion 146 will enter the first restraining groove 117 through the through hole 116 to restrain the tray 14 on the fixing base 10. When the tray 14 moves with respect to the fixing base 10, the positioning portion 118 moves in the longitudinal groove 150 and the first restraining portion 146 moves in the first restraining groove 117. In this embodiment, the first restraining portion 146 may be, but is not limited to, an I-shaped pin.

As shown in FIG. 5, the fixing base 10 may comprise a second restraining groove 119 and the operating member may comprise a second restraining portion 126. As shown in FIG. 11, when the operating member 12 is located at the closed position, the second restraining portion 126 engages with the second restraining groove 119 to restrain the operating member 12 from moving in a direction perpendicular to the fixing base 10. In this embodiment, the second restraining portion 126 may be, but is not limited to, an I-shaped pin.

As mentioned in the above, the invention utilizes the operating member disposed on the fixing base to drive the tray to move, such that the structure of the operating member is simple and does not occupy much space. Since the operating member is not disposed on the tray, the structure of the tray can be further simplified, such that it is conductive to the automated assembly of tray, circuit board and related electronic components. Furthermore, the tray and the fixing base can be quickly assembled through the cooperation between the restraining portion and the restraining groove, thereby improving assembly efficiency. Since the tray and the fixing base do not need to be equipped with inner and outer rails of the prior art, the manufacturing cost can be further reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A chassis comprising:
a fixing base;
an operating member pivotally connected to the fixing base, the operating member comprising a first linkage portion;
a tray disposed on the fixing base, the tray comprising a second linkage portion corresponding to the first linkage portion; and
a cover disposed on the fixing base and covering the tray;
wherein, when the operating member is located at a closed position, the operating member and the fixing base are locked, and the first linkage portion blocks the second linkage portion, so as to fix the tray on the fixing base; wherein, when the operating member rotates from the closed position to an opened position, the first linkage portion pushes the second linkage portion to drive the tray to move toward outside of the fixing base.

2. The chassis of claim 1, wherein, when the operating member rotates from the opened position to the closed position, the first linkage portion pushes the second linkage portion to drive the tray to move toward inside of the fixing base.

3. The chassis of claim 1, wherein the fixing base comprises a first engaging portion and the operating member comprises a second engaging portion; wherein, when the operating member is located at the closed position, the second engaging portion engages with the first engaging portion.

4. The chassis of claim 3, wherein the first engaging portion is a hole and the second engaging portion is a plunger.

5. The chassis of claim 3, wherein the fixing base comprises a pivot and a torsion spring, the operating member is pivotally connected to the pivot, and the torsion spring is disposed on the pivot and abuts against the operating member; wherein, when the second engaging portion disengages from the first engaging portion, the torsion spring drives the operating member to rotate toward the opened position.

6. The chassis of claim 5, wherein the pivot comprises two stop portions, the operating member comprises a protruding portion, and the protruding portion is located between the two stop portions.

7. The chassis of claim 1, wherein the fixing base comprises an upper plate, and the tray and the operating member are located at opposite sides of the upper plate.

8. The chassis of claim 7, wherein the fixing base further comprises a front bezel and the operating member is located between the upper plate and the front bezel.

9. The chassis of claim 1, wherein the fixing base comprises an avoidance groove; wherein, when the operating member rotates between the opened position and the closed position, the second linkage portion moves in the avoidance groove.

10. The chassis of claim 1, wherein the fixing base comprises a through hole and a first restraining groove, the through hole communicates with the first restraining groove, the tray comprises a first restraining portion, and the first restraining portion enters the first restraining groove through the through hole to restrain the tray on the fixing base.

11. The chassis of claim 10, wherein the fixing base comprises a positioning portion, the tray comprises a positioning hole and a longitudinal groove, and the positioning hole communicates with the longitudinal groove; wherein, when the positioning portion is inserted into the positioning hole, the first restraining portion is inserted into the through hole; wherein, when the tray moves with respect to the fixing base, the positioning portion moves in the longitudinal groove and the first restraining portion moves in the first restraining groove.

12. The chassis of claim 11, wherein the fixing base comprises an upper plate, and the through hole, the first restraining groove and the positioning portion are located on the upper plate.

13. The chassis of claim 11, further comprising a circuit board disposed on an installation region of the tray, wherein the first restraining portion, the positioning hole and the longitudinal groove are located beyond a range of the installation region.

14. The chassis of claim 1, wherein the fixing base comprises a second restraining groove and the operating member comprises a second restraining portion; wherein, when the operating member is located at the closed position, the second restraining portion engages with the second restraining groove.

15. The chassis of claim 1, further comprising a circuit board disposed on the tray, wherein the circuit board comprises a first electrical connector and the fixing base comprises a second electrical connector; wherein, when the operating member rotates from the closed position to the opened position, the operating member drives the tray to move toward the outside of the fixing base, such that the first electrical connector is separated from the second electrical connector; wherein, when the operating member rotates from the opened position to the closed position, the operating member drives the tray to move toward inside of the fixing base, such that the first electrical connector is connected to the second electrical connector.

16. The chassis of claim 15, wherein the circuit board comprises a handle, the fixing base comprises a side wall, the side wall comprises an indentation, and a position of the indentation corresponds to a position of the handle.

17. The chassis of claim 15, wherein the circuit board is disposed on an installation region of the tray and there is no side wall around the installation region.

18. The chassis of claim 17, wherein the tray further comprises a support member disposed on the installation region and the support member supports the circuit board.
